(19) United States
(12) Patent Application Publication
(10) Pub. No.: US 2011/0037552 A1
(43) Pub. Date: Feb. 17, 2011

(54) POLYAMIDE COMPOSITIONS AND BOBBINS MADE THEREOF

(76) Inventors: Rudy Rulkens, Margraten (NL); Wilfred W.G.J. Pelt, Van, Waalre (NL); Cheng-Yueh Kao, Shanghai (CN); Kang-Tse Hsu, Taoyuan County (CN)

Correspondence Address: NIXON & VANDERHYE, PC, 901 NORTH GLEBE ROAD, 11TH FLOOR, ARLINGTON, VA, 22203, US

(21) Appl. No.: 12/670,559

(22) PCT Filed: Jul. 17, 2008
(86) PCT No.: PCT/EP08/05865

§ 371 Date: Sep. 30, 2010

(30) Foreign Application Priority Data
Jul. 23, 2007 (EP) 07014394.6

(51) Int. Cl. H01F 27/29; C08L 77/06; H01F 27/30; H05K 13/00

(52) U.S. Cl. 336/192; 524/606; 336/198; 29/605

(57) ABSTRACT

The invention relates to a bobbin for an electrical coil comprising an plastic core made of an electrically insulating plastic material and to a polyamide composition that can be used as the electrically insulating plastic material in the bobbin, comprising a semi-crystalline semi-aromatic polyamide comprising units derived from aliphatic diamines consisting of a mixture of 10-70 mole % of a short chain aliphatic diamine with 2-5 C atoms and 30-90 mole % of a long chain aliphatic diamine with at least 6 C atoms; and units derived from dicarboxylic acids consisting of a mixture of 5-65 mole % aliphatic dicarboxylic acid and 35-95 mole % aromatic dicarboxylic acid comprising terephthalic acid, and wherein the combined molar amount of terephthalic acid and the long chain aliphatic diamine is at least 60 mole %, relative to the total molar amount of the dicarboxylic acids and diamines. The invention also relates to an electrical coil comprising the bobbin and an electrically conductive winding around the core of the bobbin.

The invention relates to a bobbin for an electrical coil comprising a plastic core made of an electrically insulating plastic material and to a polyamide composition that can be used as the electrically insulating plastic material in the bobbin. The invention also relates to an electrical coil comprising the bobbin and an electrically conductive winding around the core of the bobbin.

Such a bobbin is known from EP-1647999-A1. EP-1647999-A1 describes an inductor mounting assembly comprising an inductor body (also called sheath or bobbin) of an electrically insulating material and a conductive wire winding around the bobbin. The inductor body or bobbin can be produced of a plastic material via a moulding process such as injection moulding. To increase the inductance value of the inductor a core insert such as a ferrite element may be inserted in the bobbin. These components are mostly mounted on a printed circuit board (PCB) together with other circuit components. For that purpose, the ends of the inductor winding are connected (soldered) to metal pins. The metal pins can be inserted into the body after moulding at the desired locations, or as a better alternative according to EP164799A1, the metal pins may be integrally moulded with the inductor body. At the end of the winding process the wire is twisted several times around the ends of the metal pins and then the wire is cut off. The ends of the inductor winding are soldered to the metal pins to provide the necessary electrical connection. The pins protrude from the inductor body to permit insertion into receiving holes provided in the PCB onto which the inductor is mounted (pin-through-hole soldering), or permit placement on the solder paste for the SMD process (surface mounted device). For insulation reasons, the inductor winding is usually comprised of an electrically conductive (e.g. copper) wire covered by an insulating coating such as an enamel. In order to provide good electrical connection to the pins, the enamel must be locally removed (e.g. broken), which typically occurs via the application of heat. For this purpose the wire end wound around the pin is subject to heating, typically in excess of 300° C., (such as e.g. heating at 400° C. for 1/10 of a second) in order to “break” the insulating enamel and thus locally remove the insulating coating to expose the conductive core of the wire end. As mentioned in EP-1647999-A1, despite the short time of application, heat applied to break the insulating enamel may in fact marginally soften the plastics material of the inductor body, due to its lower softening temperature. Any undesired deformation of the inductor body or displacement of the metal pin thereof is however to be avoided.

The inductor body (sheath or bobbin) in E-164799-A1 is made of an electrically insulating plastic material, such as polybutyleneterephthalate (PBT), or others as polyamide (PA), polycarbonate (PC), polyethyleneterephthalate (PET), liquid crystal polymer (LCP), polyphenylsulfid (PPS).

Bobbins for electrical coils, called prefabricated coils, made from similar materials, are also known from WO2006/120054. The bobbins in WO2006/120054 are made of electrically insulating material, for example a plastic material with high dielectric and mechanical properties, e.g. PPS (polyphenylsulfid), PPA (polyphthalamide), or Stanyl® (polyamide-46). The prefabricated coils in WO2006/120054 are envisaged for use in an electromotor.

The known bobbins offer various problems. The winding of the wire around the core of the bobbin to form the coil imparts large forces on the core and the flanges of the bobbin. When the wire is cut off, a strong force load is applied on that part of the bobbin comprising the metal pins. For the coating on the end of the wire to be burned off prior to soldering of the wire to the metal pins, the metal pins are soaked in a soldering bath with a temperature of at least 380° C. When the prefabricated coils are subjected to a further heat treatment, for example during a casting step, a very low creep is essential, in particular when the casting material is cured in ovens at high temperature. After manufacturing of the prefabricated coils, the coils might have to be mounted on e.g. a PCB. These mounting processes nowadays more and more include processes involving higher temperatures of 250-270° C. During such a process the first soldering material used for contacting and fixing the wire ends to the metal ends must stay intact. This is the reason that ever higher melting soldering materials are used and temperatures for the first soldering bath may be as high as 380° C. or even 400° C. and higher. Although the core part of the bobbin is not exposed to this high temperature bath, heat is transferred through the metal pins, due to which the material might soften locally and the metal pins may move.

As the trend to high temperature soldering progresses, the use of current polyamide compositions in combination with current bobbin handling procedures will not be sufficient to prevent blistering.

The key parameter in controlling and thus preventing blistering of bobbins has been the control of moisture absorption in the molded parts. Blistering occurs upon super-saturation of the bobbin resin with water vapor. Much of the SMT assembly for PCBs is done in the Pacific Rim region of the world. The high temperature and humidity levels to which bobbins can be exposed can result in saturation of these bobbins with water.

The blister onset temperature is dependent upon a number of factors that include, percentage of moisture in the part, the speed of connector heating, and the peak temperature of the reflow process, crystallinity and moulding conditions (e.g. mould temperature, melt temperature), storage conditions (e.g. temperature, % RH, duration) and part design characteristics (i.e. thickness, length). Moulded parts are often stored under humid conditions to reduce the propensity of blistering during the soldering

Apart from the trend towards higher temperatures, there is also a trend of ongoing miniaturization. Due to this miniaturization the penetration depth of the heat transfer through the metal pins becomes even more critical. Consequentially higher demands are put on mechanical properties and dimensional stability of the bobbins and the materials of which the bobbins are made. The dimensional stability of the bobbin and absence of creep, at least so by large, of the plastic material during the various processing steps for making the electrical coil is very critical for the accuracy of the pin positions.

Each of the plastic materials in EP-1647999-A1 and WO2006/120054 has its own limitations. Plastics such as PBT have generally far too low softening temperatures in the range of 220-240° C. High temperature polyamides perform better than polyesters and polycarbonates. Specific problems of these polyamides include the tendency of Polyamide-46 for moisture uptake and blistering, while PPAs are generally too brittle. Both materials also suffer from insufficient dimensional stability and part integrity in very critical applications involving high temperature process steps and high mechanical loads during such processes. Polyamide-46 is known to perform much better than PA66 and PPA, but is even not sufficient. Moreover, retention of the dielectric strength of Polyamide-46 under humid conditions is not sufficient. PPS is too brittle, whereas LCP, although mostly used for these high temperature applications, is also rather brittle and known to be very expensive.

Therefore there is a need for bobbins that have a better performance during high temperature process steps involved in the production of electrical coils, both during the first soldering step (dip soldering) for connecting wire and pins as well as in subsequent soldering steps involved in mounting processes (surface mounting). In particular the bobbins should have an improved balance in properties comprising a high dimensional stability and improved blistering resistance, compared to PPA's and Polyamide-4,6 meanwhile having good mechanical properties and low creep, and a better retention of dielectric strength than corresponding bobbins made of Polyamide-46.

This aim has been achieved with a bobbin made of a polyamide composition comprising a semi-aromatic polyamide comprising units derived from aliphatic diamines and dicarboxylic acids, wherein
a) the dicarboxylic acids (A) consist of a mixture of 5-65 mole % aliphatic dicarboxylic acid and and optionally aromatic dicarboxylic acid other than terephthalic acid (A1) and 35-95 mole % terephthalic acid (A2);
b) the aliphatic diamines (B) consist a mixture of 10-70 mole % of a short chain aliphatic diamine with 2-5 C atoms (B1) and 30-90 mole % of a long chain aliphatic diamine with at least 6 C atoms (B2);
c) the combined molar amount of terephthalic acid (A2) and the long chain aliphatic diamine (B2) is at least 60 mole %, relative to the total molar amount of the dicarboxylic acids and diamines.

This semi-aromatic polyamide copolymer, for compactness and readability, will also be denoted herein as semi-aromatic polyamide X, or, even shorter, polyamide X.

The effect of the bobbin according to the invention, made of said polyamide composition, is that the dimensional stability and retention of part integrity during dip soldering processes with high peak temperatures is improved, while the blistering during the SMD soldering processes is reduced compared to polyamide-46, and several other polyamides, the bobbins have a high toughness, a low creep and a high dielectric strength, exhibited by a very low dielectric constant, and an improved retention of dielectric strength under humid conditions compared to polyamide-46.

The bobbins of the present invention have been found to have improved blister resistance over other polyamide compositions, such as PA 46,PA 6T/66 and PA 9T. This was unexpected, especially given that the water absorption or uptake of the bobbins of the present invention was substantially higher than conventional polyamide bobbins with, what was seen as “good blister resistance”, such as PA 9T.

In addition to the trend towards lead-free soldering processes, there is a trend towards further miniaturisation of bobbins. This trend has lead to a need for thin walled designs which do not warp and are able to have good mechanical properties, such as stiffness, at high temperatures. The bobbins of the present invention are able to provide a combination of improved resistance to warping and improved stiffness at high temperatures compared to conventional polyamide compositions suitable for use in bobbins. The combination of isotropic type behaviour, associated similar coefficients of linear thermal expansion in the direction parallel and normal to polymer flow, and improved stiffness at high temperature is surprising as improvements in mechanical properties, such as stiffness, are typically associated with anisotropic materials, in which enhanced performance has been derived from increased orientation of the material.

The semi-aromatic polyamide in the reinforced flame retardant polyamide composition according to the invention comprises units derived from aliphatic diamines and dicarboxylic acids. The units derived from the dicarboxylic acids can be denoted as A-A units and the units derived from the diamines can be denoted as B-B units. In line therewith the polyamides can be denoted as AABB polymers, corresponding with the classification applied in for example, Nylon Plastic handbook, Ed. M. I. Kohan, Hanser Publishers, Munich, ISBN 1-56990-189-9 (1995), page 5.

The short chain aliphatic diamine (B1) is a C2-C5 aliphatic diamine, or a mixture thereof. In other words it has 2-5 carbon (C) atoms. The short chain aliphatic diamine may be, for example, 1,2-ethylene diamine, 1,3-propanediamine, 1,4-butanediamine and 1,5-pentane diamine, and mixtures thereof. Preferably, the short chain aliphatic diamine is chosen from the group consisting of 1,4-butanediamine, 1,5-pentane diamine and mixtures thereof, more preferably 1,4-butanediamine.

The long chain aliphatic diamine (B2) is an aliphatic diamine with at least 6 carbon (C) atoms. The long chain aliphatic diamine may be linear, branched and/or alicyclic. The long chain aliphatic diamine may be, for example, 2-methyl-1,5-pentanediamine (also known as 2-methylpentamethylene diamine), 1,5-hexanediamine, 1,6-hexane diamine, 1,4-cyclohexanediamine, 1,8-octanediamine, 2-methyl-1,8-octanediamine, 1,9-nonanediamine, trimethylhexamethylene diamine, 1,10-decane diamine, 1,11-undecanediamine, 1,12-dodecanediamine, m-xylylenediamine and p-xylylenediamine, and any mixture thereof. Preferably, the long chain aliphatic diamine has 6-12 carbon atoms, and suitably is a C8- or C10 diamine. In a preferred embodiment, the long chain diamine consists for 50-100 mole %, more preferably 75-100 mole % of a diamine having 6 to 9 carbon atoms. This results in materials that have the even better high temperature properties. More preferably, the long chain aliphatic diamine is chosen from the group consisting of 1,6-hexane diamine, 2-methyl-1,8-octanediamine, 1,9-nonanediamine, and mixtures thereof, more preferably 1,6-hexane diamine. The advantage of this preferred choice, and in particular of the more preferred choice of 1,6-hexane diamine is that the high temperature properties of the copolyamide according to the invention are even better.

The aliphatic dicarboxylic acid may be straight chain, branched chain and/or alicyclic, and the number of carbon atoms therein is not specifically restricted. However, the aliphatic dicarboxylic acid preferably comprises a straight chain or branched chain aliphatic dicarboxylic acid with 4 to 25 carbon atoms, or a mixture thereof, more preferably 6-18 and still more preferably 6-12 carbon atoms. Suitable aliphatic dicarboxylic acid are, for example, adipic acid (C6), 1,4-cyclohexane dicarboxylic acid (C8), suberic acid (C8), sebacic acid (C10), dodecanoic acid (C12) or a mixture thereof. Preferably, the aliphatic dicarboxylic acid is a C6-C10 aliphatic dicarboxylic acid, including adipic acid, sebacic acid or a mixture thereof, and more the aliphatic dicarboxylic acid is a C6-C8 aliphatic dicarboxylic acid. Most preferably the aliphatic dicarboxylic acid is adipic acid.

The aromatic dicarboxylic acid may comprise, next to terephthalic acid, other aromatic dicarboxylic acids, for example isophthalic acid and/or naphthalane dicarboxylic acid.

The semi-aromatic polyamide may suitably comprises, next to terephthalic acid, aliphatic dicarboxylic acids or aliphatic dicarboxylic acids and aromatic dicarboxylic acids other than terephtalic acid. Preferably, the amount of the aromatic dicarboxylic acid other than terephthalic acid is less than 50 mole %, more preferably less than 25 mole %, relative to the total molar amount of aliphatic dicarboxylic acid and aromatic dicarboxylic acids other than terephtalic acid (A1).

In the semi-aromatic polyamide in the composition according to the invention, the short chain aliphatic diamine (B1) makes up for 10-70 mole % and the long chain aliphatic diamine (B2) makes up for the remaining 30-90 mole % of the aliphatic diamine units (B).

Preferably, the molar amount of the short chain aliphatic diamine is at most 60 mole %, more preferably 50 mole %, 40 mole %, or even 35 mole % relative to the molar amount of short chain and long chain diamines. An advantage of the copolyamide with such a lower molar amount of the short chain diamine is that for the copolyamide with a given Tm the blistering behaviour improves.

Also preferably, the molar amount of the short chain aliphatic diamine in the semi-aromatic polyamide is at least 15 mole %, more preferably, at least 20 mole %, relative to the total molar amount of short chain aliphatic diamine and long chain aliphatic diamine. The higher the molar amount of the short chain aliphatic diamine the better is the thermal stability of the polyamide.

The aliphatic dicarboxylic acid and, if present, aromatic dicarboxylic acids other than terephtalic acid (A1) make up for 5-65 mole % and the terephthalic acid (A2) makes up for the remaining 35-95 mole % of the dicarboxylic acid units (A).

Preferably, the dicarboxylic acids consist for at least 40 mole %, more preferably at least 45 mole %, or even at least 50 mole %, of terephtalic acid. The advantage of an increased amount of terephtalic acid, is that the high temperature properties are further improved. Also preferably the amount of the aliphatic dicarboxylic acid and optionally aromatic dicarboxylic acids other than terephtalic acid (A1) is at least 10 mole %, more preferably at least 15 mole % of the dicarboxylic acid. This higher amount has the advantage that the composition has a better processability.

In a highly preferably embodiment, the dicarboxylic acids (A) consist of 50-85 mole % of terephthalic acids (A2) and 50-15 mole % of aliphatic dicarboxylic acid and optionally aromatic dicarboxylic acids other than terephtalic acid (A1), relative to the molar amount of dicarboxylic acids and the aliphatic diamines (B) consist of 40-80 mole % long chain diamines (B2) and 60-20 mole % short chain diamines (B1), relative to the total molar amount of aliphatic diamines. More preferably, the amount of the aromatic dicarboxylic acid other than terephthalic acid therein, if present at all, is less than 25 mole %, relative to the total molar amount of aliphatic dicarboxylic acid and aromatic dicarboxylic acids other than terephthalic acid (A1). This preferred composition gives a better overall balance in blistering properties, dielectric breakdown strength, processing behaviour and mechanical properties.

Whereas the minimum amount for the long chain aliphatic diamine (B2) is 30 mole %, relative to the total molar amount of aliphatic diamines, and the minimum amount for the terephtalic acid (A2) is 35 mole %, relative to the molar amount of dicarboxylic acids, the combined molar amount of the terephtalic acid (A2) and the long chain aliphatic diamine (B2) is at least 60 mole %, relative to the total molar amount of the dicarboxylic acids and diamines. The consequence thereof is that when the relative amount of the long chain aliphatic diamine is the minimal 30 mole %, the relative amount of terephtalic acid is at least 90 mole %. Analogously, when the relative amount of terephtalic acid is the minimal 35 mole %, the relative amount of the long chain aliphatic diamine is at least 85 mole %.

In another highly preferably embodiment, the sum of the molar amount of terephtalic acid (A2) and the long chain aliphatic diamine (B2) is at least 65 mole %, more preferably at least 70 mole % and still more preferably at least 75 mole %, relative to the total molar amount of dicarboxylic acids and diamines. The advantage of the polyamide with the sum of the molar amount of terephtalic acid (A2) and the long chain aliphatic diamine (B2) being higher is that the polyamide combines higher dielectric breakdown values with a better thermal stability and good melt processability. Suitably, the said sum is in the range of 70-85 mole %, or even 75-80 mole %, relative to the total molar amount of dicarboxylic acids and diamines.

Next to the A-A-B-B units derived from dicarboxylic acids (AA) and diamines (BB), the polyamide according to the invention may comprise units derived from other components, such as aliphatic aminocarboxylic acids (AB units) and the corresponding cyclic lactams, as well as small amounts of a branching agent and/or chain stoppers.

Preferably, the polyamide according to the invention comprises at most 10 mass %, more preferably at most 8 mass %, and still more preferably at most 5 mass %, relative to the total mass of the polyamide, of units derived from components other than dicarboxylic acids and diamines. Most preferably the polyamide according to the invention does not comprise such other components at all and consists only of A-A-B-B units derived from dicarboxylic acids and diamines. The advantage is better dielectric properties and better retention of dielectric and mechanical properties at elevated temperature and high humidity.

Preferably, the semi-aromatic polyamide has a glass transition temperature (Tg) of more than 100° C., more preferably at least 110° C., or even at least 120° C. Preferably the Tg is at most 140° C., more preferably at most 130° C. Also preferably, the semi-aromatic polyamide has a melt temperature (Tm) of at least 295° C., preferably at least 300° C., more preferably at least 310° C. Preferably the Tg is at most 340° C., more preferably at most 330° C. A higher Tg results in better dielectric properties and retention of dielectric strength in particular under humid conditions. A high Tm result in better blistering resistance. The advantages of the Tg and Tm being within these limits is has a better balance in blistering resistance, dimensional stability and processing behaviour.

With the term melting point (temperature) is herein understood the temperature, measured according to ASTM D3417-971D3418-97 by DSC with a heating rate of 10° C./min, falling in the melting range and showing the highest melting rate. With the term glass transition point is herein understood the temperature, measured according to ASTM E 1356-91 by DSC with a heating rate of 10° C./minute and determined as the temperature at the peak of the first derivative (with respect of time) of the parent thermal curve corresponding with the inflection point of the parent thermal curve.

The semi-aromatic polyamide may have a viscosity varying over a wide range. It has been observed that the relative viscosity may be as low as 1.6 ore even lower while still retaining good mechanical properties for the reinforced flame retardant composition. Here the relative viscosity is measured in 96% sulphuric acid according to method to ISO 307, fourth edition. Preferably the relative viscosity is at least 1.7, more preferably 1.8 or even 1.9. Retention of mechanical properties is really important for such moulded parts, which is still the case at such a low relative viscosity. Also preferably the relative viscosity is less than 4.0, more preferably less than 3.5 and still more preferably less than 3.0. This lower has relative viscosity the advantage that the flow during moulding is better and moulded parts with thinner elements can be made.

The composition according to the invention may comprise the semi-aromatic polyamide in an amount varying over a wide range. Suitably the amount is in the range of 25-80 wt. %, more preferably the composition comprises 25-60 wt. %, or even 30-50 wt. % of the semi-aromatic polyamide.

The said polyamide composition may comprise next to the semi-aromatic polyamide one or more other components. Suitably the polyamide composition comprises at least one of the following components: inorganic fillers, reinforcing agents, flame retardants, other polymers, and auxiliary additives, being additives commonly employed with injection mouldable polyamide composition.

Other polymers are herein understood to be polymeric materials other than the said semi-aromatic polyamide and other than polymeric flame retardants. The other polymers can be thermoplastic polymers, such as thermoplastic polyamides other than the said semi-aromatic polyamide, thermoplastic polyesters and PPS, and rubbers. The other polymers can include oligomeric and polymeric flow enhancers, impact modifiers and toughening agents. The other polymers, when used at all, are typically used in an amount of less than 30 wt. %, relative to the weight of the semi-aromatic polyamide. Preferably, the amount is less than 25 wt. %, more preferably less than 20 wt. % and most preferably less than 10 wt. %, relative to the weight of the semi-aromatic polyamide. Suitably, small amounts of at least 1 wt. %, or at least 2 wt. % are used.

The polyamide composition preferably comprises a flame retardant, optionally combined with a flame retardant synergist, and more preferably complies with a UL or other regulatory agency flammability rating for safety reasons.

The flame retardant system may comprise a halogenated flame retardant and/or a halogen free flame retardant, and next to the said flame retardant or combination thereof optionally also a flame retardant synergist. The halogenated flame retardant may be a brominated polymer, for example a brominated polystyrene, a polybromostyrene copolymer, a brominated epoxy resin and/or a brominated polyphenylene oxide. Suitably, the halogenated flame retardant is a brominated polystyrene with a high bromine content, for example in the range of 61-70 wt. %. The higher bromine content allows lower loadings of flame retardant, and for better flow properties. The halogen free flame retardant may suitably be a nitrogen containing flame retardant, a phosphorous containing flame retardant and/or a nitrogen and phosphorous containing flame retardant. Suitable halogen free flame retardants are for example phosphates, in particular polyphosphates, such as melamine polyphosphates, and phosphinates, in particular metal salts of organic phosphinates, such as calcium—and aluminium diethylphosphinate. Examples of suitable synergists are antimony compounds like antimony trioxide, antimony pentoxide, and sodium antimonite, and other metal oxide, and zinc borate and other metal borates. Preferably, the synergist is zinc borate, since this provides improved blister resistance.

Suitably, the flame retardant system is present in a total amount of 1-40 wt. %, preferably 5-35 wt. %, relative to the total weight of the composition. Preferably the flame retardant is present in an amount of 5-30 wt. %, more preferably 10-25 wt. %, and the synergist is preferably present in an amount of 0-15 wt. %, more preferably 1-10 wt. %, and still more preferably 5-10 wt. %, relative to the total weight of the composition.

The polyamide composition preferably comprises a reinforcing agent. This improves the properties of the polyamide composition and the bobbin made thereof drastically, in particularly the dimensional stability of the bobbin during the dip soldering step.

The reinforcing agent can include fibrous materials like glass fibres such as low-alkali E-glass, carbon fibres, potassium titanate fibres, and whiskers, of which glass fibres are preferred, and mineral reinforcing agents, which typically are plate like or fibrous shaped materials, like mica and nano-clays. Suitably the reinforcing agent is present in an amount of 5-50 wt. %, preferably 15-45 wt. %, more preferably 25-40 wt. % relative to the total weight of the composition. As mentioned before the reinforcing agent has a strong increasing effect on the modulus of the composition above Tg, which increase is larger than in several other polyamides.

Typical examples of fibrous reinforcing agents that can be used include glass fibres carbon fibres, potassium titanate fibres, and whiskers, of which glass fibres are preferred. Sizing agents can be used with such reinforcing agents or fillers, if desired. Suitable glass fibres that can be used in preparing the compositions of this invention are commercially available. Suitably the reinforcing agent is present in an amount of 5-50 wt. %, preferably 15-45 wt. %, more preferably 25-40 wt. % relative to the total weight of the composition.

Other additives that may be comprised by the inventive composition include inorganic fillers, CTI improving agents and auxiliary additives used in injection moulding compounds. The inorganic fillers are for example, glass flakes and mineral filler such as glass spheres or micro balloons, clay, kaoline, like calcined kaolin, wollastonite, and talc, and other minerals, and any combination thereof. The amount of inorganic fillers may be varied over a large range, but suitably is in the range of 0-50 wt. %, preferably 1-25 wt. %, relative to the total weight of the composition.

Preferably, the polyamide composition comprises at least a CTI improving agent, more preferably a CTI improving agent and an inorganic filler, a fibrous reinforcing agent, or a flame retardant, or any combination thereof. Suitable additives for improving the CTI include, for example, (i) apolar polymers like polyolefines, such as polyethylene and/or ethylene copolymers, and acrylic impact modifiers, and (ii) inert fillers, like bariumsulphate and metal borates, such as zinc borate and alkaline earth metal borate like calcium borate, mixed oxides of alkali metals and boron, mixed oxides of zinc and boron, zinc sulfide and compressed pulverized talc, or any combination thereof. Preferably, the CTI improving agent comprises zinc borate, or a mixture of an apolar polymer and any one or more of the foregoing inert fillers, more preferably a mixture of an olefin-based polymer and zinc borate. The CTI improving additive is suitably used in a total amount in the range between 0 and 15 wt. %, for example in the range of 0.1-12 wt. %, and preferably 0.2-10 wt. %. Preferred amounts for the inert filler are 1-12 wt. % , more preferably 3 to 10, and for the apolar polymer 1 to 10 wt. %, more preferably 3-8 wt. %. Herein the weight percentages are relative to the total weight of the polymer composition.

CTI is a measure of the resistance of a material to the propagation of arcs (tracks) along its surface under wet conditions. The CTI can be determined in accordance with the IEC 112-1979 (3rd edition) procedure.

Thermoplastic polyamides such as glass-filled nylon 6, nylon 6,6 and nylon 4,6 and other high temperature nylons, are considered of interest for the production of articles having electrical and electronic applications. For many of these applications, electrical resistance is required in order to effectively utilize such polymers in such applications. Unfortunately, a shortcoming of many polyamide thermoplastics is their tendency to allow the passage of electric current over their surface when wet with water. This problem is exacerbated by the presence of glass reinforcement or a bromine-containing flame retardant, and the presence of both glass reinforcement and a bromine-containing flame retardant makes the problem even worse.

An advantage of the bobbin according to the invention is a high CTI (comparative tracking index), and likewise a high dielectric strength, exhibited by the polyamide composition comprising the said semi-aromatic polyamide X of which these bobbins are made. The CTI value thereof is much higher than for corresponding products made of, for example, Polyamide 46 and Polyamide 9T.

In another embodiment of the present invention, there is provided a polyamide composition comprising a semi-aromatic polyamide comprising units derived from aliphatic diamines and dicarboxylic acids and at least a CTI improving additive, wherein:
a. the dicarboxylic acids (A) consist of a mixture of 5-65 mole % aliphatic dicarboxylic acid and optionally aromatic dicarboxylic acid other than terephthalic acid (A1) and 35-95 mole % terephthalic acid (A2);
b. the aliphatic diamines (B) consist a mixture of 10-70 mole % of a short chain aliphatic diamine with 2-5 C atoms (B1) and 30-90 mole % of a long chain aliphatic diamine with at least 6 C atoms (B2);
c. the combined molar amount of terephthalic acid (A2) and the long chain aliphatic diamine (B2) is at least 60 mole %, relative to the total molar amount of the dicarboxylic acids and diamines.

The high CTI values of the polyamide composition comprising the said semi-aromatic polyamide make the bobbins highly suitable for high voltage applications. Typically CTI values above 400 V are achieved. When formulated with regular glass fibres as reinforcement agents and regular flame retardants, including halogen free flame retardants based on melamine and/or phosphates derivatives, for example melamine polyphosphates, and metal salts of phosphinates, and halogen containing flame retardant systems based on halogen containing polymers like polybromostyrene, and flame retardant synergists, like zinc borate, and leaving out, or limiting additives that reduce the CTI, CTI values of 500 V and above can be reached. Selection of additives that are neutral in respect of the CTI or have a positive effect on the CTI, and avoiding or limiting the amount of additives that have a negative effect on the CTI, can be selected by the person, skilled in the art of making injection moulding products complying with CTI requirements in general, on the basis of general knowledge and routine experiments. The high CTI values, in combination with the good dimensional stability and part integrity can advantageously be used in industrial high voltage bobbins. Preferably, the CTI of flame retardant material according to the invention used herein has a CTI, of at least 500 V, more preferably at least 600 V.

Auxiliary additives, which the polyamide composition can contain, include colorants such as dyes and pigments, low molecular weight flow enhancers such as dodecanedioic acid, stabilizers such as antioxidants, ultraviolet stabilizers and heat stabilizers, compatibilizers such as silane compounds, and processing aids such as mould release agents and nucleating agents. The auxiliary additives are typically used in individual amounts of less than 2.0 wt. %, preferably less than 1.0 wt. %, and in a total amount of preferably less 10 wt. %, more preferably less than 5 wt. %, wherein the wt. % is relative to the total weight of the polyamide composition.

In a preferred embodiment of the invention, the composition consists of
25-80 wt. % of the semi-aromatic polyamide, and
0.1-15 wt. % of a CTI improving additive, as well as
0-50 wt. % of the reinforcing agent,
0-40 wt. % the flame retardant system, and
0-25 wt. % polymers other than the semi-aromatic polyamide and polymeric flame retardant,
0-25 wt. % inorganic fillers, and/or
0-5 wt. % auxiliary additives,
   wherein the weight percentages (wt. %) are relative to the total weight of the composition.

In another preferred embodiment of the invention, the bobbin is made of a flame retardant composition consisting of
25-80 wt. % of the semi-aromatic polyamide,
5-50 wt. % of the reinforcing agent, and
5-40 wt. % the flame retardant system, as well as
0-15 wt. % of a CTI improving additive,
0-25 wt. % polymers other than the semi-aromatic polyamide and polymeric flame retardant,
0-25 wt. % inorganic fillers, and/or
0-5 wt. % auxiliary additives,
   wherein the weight percentages (wt. %) are relative to the total weight of the composition.

The other polymers, inorganic fillers and auxiliary additives are optional components in both these embodiments, meaning that either none or only one of them or a combination of only two or all three may be present. Suitably, at least an auxiliary additive is present.

More preferably, the composition consists of
30-50 wt. % of the semi-aromatic polyamide,
0.2-10 wt. % of a CTI improving additive,
15-45 wt. % of the reinforcing agent,
5-35 wt. % of the flame retardant system,
0.1-5 wt. % of auxiliary additives,
0-25 wt. % inorganic fillers, and
0-25 wt. % of polymers not included in the components mentioned here above.

The copolyamide according to the invention can be prepared in various ways known per se for the preparation of polyamides and copolymers thereof. Examples of suitable processes are for example described in Polyamide, Kunststoff Handbuch 3/4, Hanser Verlag (München), 1998, ISBN 3-446-16486-3. The polymer composition comprising the semi-aromatic polyamide X, and one or more additives, including the CTI improving additives, the flame retardant system, the reinforcing agent, or another additive, can be made by standard compounding techniques known by the person skilled in the art, for example in a twin screw extruder.

The compounded polymer compositions of this invention can be processed in conventional ways. For example, the compounds can be transformed into the final articles by appropriate processing techniques such as injection molding, compression molding, extrusion, or like procedures.

The bobbin according to the invention can be made from the polyamide composition by injection moulding processes.

The core of the bobbin may have any shape suitable for making electrical coils thereof, having for example, a circular or rectangular cross sectional shape, or rectangular with rounded off edges.

The bobbin may comprise a core part, the core part having two end sections, and two flanges, each positioned at an end section of the core. Suitably the bobbin comprising the core part and the two flanges is a shaped body having a cross-sectional shape like an H, wherein the horizontal line constitutes a schematic representation of the core part, and the two vertical lines constitute a schematic representation of the two flanges.

The bobbin may also comprise a core part having a cavity or through opening designed to receive and house an element of a metallic material, such as a tooth of a stator unit of an electromotor, or an element of a magnetic material such as a ferrite core for an inductor.

The bobbin according to the invention suitably comprises at least one cavity or seat for receiving a metal pin and/or at least one integrally moulded metal pin.

The present invention also relates to an electrical coil comprising the bobbin according to the invention and an electrically conductive winding around the core of the bobbin.

The bobbin in the electrical coil according to the invention can be any bobbin described here above comprising polyamide composition comprising a semi-aromatic polyamide, or any preferred embodiment thereof.

The electrically conductive winding in the electrical coil, may be, for example an electric wire, which may have a cross section that can be circular, or rectangular, or of some other shape, or a flat cable.

In a preferred embodiment, the electrical coil comprises a bobbin comprising an plastic core with one or more integrally moulded metallic pins, a wire wound around the core forming a conductive coil, the wire having at least one wire end attached to one integrally moulded metallic pin and a soldering material providing electrical contact between the one integrally moulded metallic pin and the one end of the wire.

In another preferred embodiment, the conductive coil is embedded in and isolated by an external layer consisting of a polyamide composition comprising a semi-aromatic polyamide as described above, or any preferred embodiment thereof.

The invention also relates to a process for making an electrical coil according the invention, comprising winding an electrically conductive wire comprising a coating layer around the core of the bobbin, attaching an end of the wire to an metallic pin, burning off the coating layer from the end of the wire and soldering the end of the wire to the metallic pin.

Preferably, the process according to the invention comprises one of the following steps, or a combination thereof:
an attachment step wherein the wire is wound at least one time around the integrally moulded metallic pin and cut to retain a wire end wound at least one time around the integrally moulded metallic pin;
a dip soldering step for soldering at least one wire end to an integrally moulded metallic pin, wherein the wire end and the integrally moulded metallic pin are dipped into a melt of a soldering material having a temperature of at least 380° C.;
an injection moulding step wherein the conductive coil is overmoulded with a layer of a polyamide composition as described above, or any preferred embodiment thereof.

Preferably, the soldering material includes a lead free alloy soldering masses.

Also preferably the melt of the soldering material has a temperature in the range of 380° C.-500° C.

The electrical coil according to the invention can advantageously be integrated into an electrical and/or electronic assembly comprising a part and the electrical coil mounted upon the part.

Envisaged electrical and/or electronic assemblies include transformers, inductors, filters, relays, electromotors, PCBs. In the case of a transformer, inductor, or relay, the bobbin is a permanent container for the wire, acting to form the shape of the coil and ease assembly of the windings into or onto the magnetic core.

Inductors are frequently used as components in a wide variety of electronic/electrical circuits. Exemplary applications of inductors are e.g. so-called “chokes” currently used for interference suppression e.g. in motors of house appliances in order to prevent RF interference on radio, TV equipment and the like or in electronic ballasts of fluorescent lamps.

### EXPERIMENTAL

The polyamide compositions used in the preparations of the bobbins were prepared by first preparing the polyamide polymer for Examples 1 to 5 (E-1 to E-5) and comparative examples (CE) A, B, C and F. Comparative examples D and E were commercial formulations.

### Polymer Preperation

### E-1 Polymer: PA-6T/4T/46 (Mole Ratio 67.5/21.3/11.2)

A mixture of 179.8 g tetramethylene diamine, 347.25 g hexamethylene diamine, 537 g water, 0.36 g sodium hypophosphite monohydrate, 72.36 g adipic acid and 653.38 g terephthalic acid was stirred in a 2.5 liter autoclave with heating and with the removal of water by distillation. It is noted that a slight excess of tetramethylene diamine of about 2-4 wt. % has been used, compared to the composition of the calculated polyamide composition, to compensate for the loss of tetramethylene diamine during the preparation of the polyamide. After about 27 minutes a 91 wt. % aqueous salt solution was obtained. In this process the temperature increased from 169° C. to 223° C. The polymerisation was effected at increasing temperatures of 210° C. to 226° C. for 21 minutes, during which the pressure rose to 1.3 MPa, after which the autoclave's contents were flashed and the solid product was cooled further under nitrogen. The prepolymer thus obtained was subsequently dried in a drying kiln for several hours heating at 125° C. under vacuum and a stream of nitrogen of 0.02 MPa. The dried prepolymer was post-condensed in the solid phase in a metal tube reactor (d=85 mm) for several hours heating at 200° C. under a stream of nitrogen (2400 g/h) and then under a stream of nitrogen/water vapour (3/1 weight ratio, 2400 g/h)) for 2 hours at 225° C. and 40 hours at 260° C. Then the polymer was cooled to room temperature.

### E-2 Polymer: Preparation of PA-6T/4T/46 (Mole Ratio 74.5/10/15.5)

In the same way as for the E-1 Polymer a mixture of 127.09 g tetramethylene diamine, 350.05 g hexamethylene diamine, 487 g water, 0.66 g sodium hypophosphite monohydrate, 91.59 g adipic acid and 567.48 g terephthalic acid was stirred in a 2.5 liter autoclave with heating so-that an 91 wt. % aqueous salt solution was obtained after 22 minutes. In this process the temperature increased from 176° C. to 212° C. The polymerisation was effected at increasing temperatures of 220° C. to 226° C. for 22 minutes, during which the pressure rose to 1.4 MPa. The prepolymer thus obtained was subsequently dried in a drying kiln for several hours heating at 125° C. and 180° C. under vacuum and a stream of nitrogen of 0.02 Mpa. The prepolymer was post-condensed in the solid phase in a metal tube reactor (d=85 mm) for several hours heating at 190° C. and 230° C. under a stream of nitrogen (2400 g/h) and then under a stream of nitrogen/water vapour (3/1 weight ratio, 2400 g/h) for 96 hours at 251° C. Then the polymer was cooled to room temperature.

E-3 Polymer: Preparation of PA-6T/56 (mole ratio 85/15) equivalent to PA-6T/5T/66 (Mole Ratio 70/15/15)

A mixture of 55.3 g of pentamethylene diamine (98 wt. %), 529.7 g aqueous hexamethylene diamine (59.6 wt. %), 360.4 g water, 0.5 g sodium hypophosphite monohydrate, 67.2 g adipic acid and 433.04 g terephthalic acid was stirred in a 2.5 litre autoclave with heating and with distillative removal of water. After 35 minutes a 90 wt. % aqueous salt solution was obtained, while the temperature rose from 170° C. to 212° C. Then the autoclave was closed. The polymerisation was effected at increasing temperatures of 212° C. to 250° C. for 25 minutes. The mixture was stirred at 250° C. for 15 min, during which the pressure rose to 2.9 MPa, after which the autoclave's contents were flashed and the solid product was cooled further under nitrogen. The prepolymer was post-condensed in the solid phase in a metal tube reactor (d=85 mm) for several hours heating at 200° C. under a stream of nitrogen (2400 g/h) and then under a stream of nitrogen/water vapour (3/1 weight ratio, 2400 g/h)) for 2 hours at 230° C. and 24 hours at 260° C. Then the polymer was cooled to room temperature.

### E-4 Polymer: Preparation of PA-6T/5T/56 (Mole Ratio 75.5/15/9.5)

A mixture of 78.4 g of pentamethylene diamine (98 wt. %), 473.3 g aqueous hexamethylene diamine (59.6 wt. %), 382.56 g water, 0.5 g sodium hypophosphite monohydrate, 42.6 g adipic acid and 461.5 g terephthalic acid was stirred in a 2.5 litre autoclave with heating and with distillative removal of water. After 35 minutes a 90 wt. % aqueous salt solution was obtained, while the temperature rose from 170° C. to 212° C. Then the autoclave was closed. The polymerisation was effected at increasing temperatures of 212° C. to 250° C. for 25 minutes. The mixture was stirred at 250° C. for 15 min, during which the pressure rose to 2.8 MPa, after which the autoclave's contents were flashed and the solid product was cooled further under nitrogen. The prepolymer was subsequently dried and post-condensed in the solid phase in the same way as the E-1 polymer. Then the polymer was cooled to room temperature.

### E-5 Polymer: Preparation of PA-6T166156 (Mole Ratio 76.5/12/11.5)

A mixture of 36.9 g of pentamethylene diamine (98 wt. %), 553.0 g aqueous hexamethylene diamine (59.6 wt. %), 351.2 g water, 0.5 g sodium hypophosphite monohydrate, 105.8 g adipic acid and 391.4 g terephthalic acid was stirred in a 2.5 litre autoclave with heating and with distillative removal of water. After 35 minutes a 90 wt. % aqueous salt solution was obtained, while the temperature rose from 170° C. to 212° C. Then the autoclave was closed. The polymerisation was effected at increasing temperatures of 212° C. to 250° C. for 25 minutes. The mixture was stirred at 250° C. for 20 min, during which the pressure rose to 2.8 MPa, after which the autoclave's contents were flashed and the solid product was cooled further under nitrogen. The prepolymer was subsequently dried and post-condensed in the solid phase in the same way as the E-1 polymer. Then the polymer was cooled to room temperature.

### CE-A Polymer: PA6T/66 (Molar Ratio 60/40)

In the same way as for Polymer I a mixture of 520 g hexamethylene diamine, 537 g water, 0.36 g sodium hypophosphite monohydrate, 330 g adipic acid and 420 g terephthalic acid was stirred in a 2.5 litre autoclave with heating so-that an 91 wt. % aqueous salt solution was obtained after 27 minutes. In this process the temperature increased from 169° C. to 223° C. The polymerisation was effected at increasing temperatures of 210° C. to 226° C. for 21 minutes, during which the pressure rose to 1.3 MPa. The prepolymer was subsequently dried and post-condensed in the solid phase in the same way as the E-1 Polymer. Then the polymer was cooled to room temperature.

### CE-B,C Polymer: PA 46

In the same way as for Polymer I a mixture of 430.4 g tetramethylene diamine, 500 g water, 0.33 g sodium hypophosphite monohydrate and 686.8 g adipic acid was stirred in a 2.5 liter autoclave with heating so-that a 90 wt. % aqueous salt solution was obtained after 25 minutes. In this process the temperature increased from 110° C. to 162° C. The polymerisation was effected at increasing temperatures of 162° C. to 204° C. in during which the pressure rose to 1.3 MPa. The prepolymer was subsequently dried and post-condensed in the solid phase in the same way as for the E-1 polymer. Then the polymer was cooled to room temperature.

### Comparative Example CE-F: Preparation of PA-6T/5T (Mole Ratio 56/44)

A mixture of 201.4 g of pentamethylene diamine, 300.8 g hexamethylene diamine, 521.1 g water, 0.65 g sodium hypophosphite monohydrate and 722.18 g terephthalic acid was stirred in a 2.5 litre autoclave with heating and with distillative removal of water. After 27 minutes a 90 wt. % aqueous salt solution was obtained, while the temperature rose from 170° C. to 211° C. Then the autoclave was closed. The polymerisation was effected at increasing temperatures of 211° C. to 250° C. in 15 minutes. The mixture was stirred at 250° C. for 29 min, during which the pressure rose to 2.9 MPa, after which the autoclave's contents were flashed and the solid product was cooled further under nitrogen. The prepolymer was subsequently dried and post-condensed in the solid phase in the same way as for the E-3 polymer. Then the polymer was cooled to room temperature.

### Compound Preparation

E-1 to E-5, CE-A to C and CE-F also included the following components:
Standard glass fibre grades for polyamides;
Flame retardant: brominated polystyrene (Saytex® HP3010 available from Albermarle);
Flame retardant synergist: zinc borate (Firebrake® 500 available from Luzenac); and
Auxiliary additives comprising a release agent and a stabilizing package,

Comparative Experiments D and E were based on commercial products: CE-D being Zytel HTNFR52G30BL, a PA6T/66 product from DuPont, and CE-E being Genestar GN2332 BK, a PA9T product from Kururay. Conventional analytical techniques were used to estimate the proportions of brominated polystyrene, sygnergists and auxiliary additives used in these commercial products. Analysis of the PA9T product from Genestar revealed that the polyamide component consisted of PA8T and PA9T in a molar ratio of approximately 20:80.

The compounds of E-1 to E-5, CE-A to C and CE-F were prepared on a Werner & Pfleiderer KSK 4042D extruder set on a 325° C. flat temperature. All components were dosed into the feed port of the extruder, except for the glass fibers that were dosed separately into the melt via a side feed port. The polymer melt was degassed into strands at the end of the extruder, cooled and chopped into granules.

### Injection Moulding:

The materials described above were pre-dried prior to use in injection moulding, by applying the following conditions: the copolyamides were heated under vacuum of 0.02 Mpa to 80° C. and kept at that temperature and pressure for 24 hrs while a stream of nitrogen was passed. The pre-dried materials were injection moulded on an Arburg 5 injection moulding machine with a 22 mm screw diameter and a Campus UL 0.8 mm 2 body injection mould. The temperature of the cylinder wall was set at 345° C., and the temperature of the mould was set at 140° C. The Campus UL bars thus obtained were used for further tests.

TABLE I
Compound compositions

| | E-1 | E-2 | E-3 | E-4 | E-5 | CE-A | CE-B | CE-C | CE-D | CE-E | CE-F |
|---|---|---|---|---|---|---|---|---|---|---|---|
| Polymer % | 42 | 37 | 42 | 42 | 42 | 42 | 37 | 42 | 41 | 41 | 42 |
| Glass fibers | 30 | 40 | 30 | 30 | 30 | 30 | 40 | 30 | 30 | 33 | 30 |
| Brominated | 20 | 16 | 20 | 20 | 20 | 20 | 16 | 20 | 24 | 20 | 20 |
| polystyrene | | | | | | | | | | | |
| Synergist | 7 | 6 | 7 | 7 | 7 | 7 | 6 | 7 | 4 | 5 | 7 |
| Aux. additives | 1 | 1 | 1 | 1 | 1 | 1 | 1 | 1 | 1 | 1 | 1 |

### Test Methods

Relative viscosity (RV) was determined in 1 mass % formic acid solution.
Spiral flow was determined on spiral cavity with dimensions 280×15×1 mm at a temperature 10° C. above the melt temperature of semi-aromatic polyamide X at 80 MPa effective injection pressure.

### Thermal Characterization by DSC:

Melting point (Tₘ) and glass transition temperature (T_{g}) were determined with the aid of differential scanning calorimetry (DSC) (2nd run, 10° C./min.) according to ASTM D3417-97 E793-85/794-85.
E-modulus was determined in a tensile test at 23° C. and 5 mm/min, according to ISO 527.
Impact test (notched-Charpy) was determined at 23° C. according to ISO 179/1A.

### Water/Humidity Absorption Tests:

Pre-dried samples (0.8 mm UL bars) were conditioned in a humidifying cabinet or a container of distilled water at a preset temperature and humidity level, the weight increase was monitored over time until the saturation level was reached. The weight increase at saturation level was calculated as a percentage of the starting weight of the pre-dried sample.

### Blistering Performance Under Reflow Soldering Conditions.

For the blistering performance under reflow soldering conditions a large number of pre-dried samples were conditioned in a humidifying cabinet at a preset temperature and humidity level in the same way as for water absorption test described above. At different time intervals individual samples (in lots of 10) were taken from the cabinet, shortly cooled at ambient conditions to room temperature, put in a reflow oven and subjected to temperature conditions as applied in reflow soldering processes. The temperature profile applied was the following. First the samples were preheated with a heating ramp of average 1.5° C./sec to reach a temperature of 140° C. after 80 seconds, after which the sample was heated more gradually to reach a temperature of 160° C. after 210 sec from the start. Then, the sample was heated to 260° C. with a initial heating ramp of about 6° C./sec to reach a temperature of 220° C. after 220 sec and a more gradual heating rate of 2° C./sec to reach a temperature of 260° C. after 290 sec from the start. After that, the sample was cooled down to 140° C. in 20 sec. Then the 10 samples were taken from the oven, let cool to room temperature and inspected for the presence of blisters. For each condition period in the humidifying cabinet the percentage of samples that showed occurrence of blistering was rated. The percentage of samples with blisters was recorded.
Coefficient of linear thermal expansion was determined in accordance with ISO 11359-1/-2.
Dielectric constant of the sample (DAM) was determined in accordance with IEC 60250 at a frequency of 3 Ghz at 23° C.
Dielectric strength of the sample (DAM) was determined in accordance with IEC 60243-1.
Comparative Tracking Index was determined in accordance with IEC 60112.
Heat Deflection Temperature was determined in accordance with ISO 75-1/-2 with a load of 1.8 MPa applied.
All compounds complied with UL-94-V0 for 0.8 mm test bars.

### Results

The results of the experimentation are presented in Table 2.

As illustrated in Table 2, the compositions of the present invention overcome the problems associated with soldering bobbins with conventional polyamide compositions by providing a polyamide composition with improved blistering resistance, dimensional stability and mechanical properties at high temperatures, while at least retaining the required processing, electrical and flame retardant properties of conventional compositions.

The compositions of the present invention have been found to provide improved blister performance against polyamide compositions suitable for bobbin applications. Compositions under the scope of the present invention were found to comply with the requirements of the JEDEC 2/2a blister test (IPC/JEDEC J-STD-020C July 2004). In contrast, none of the comparative examples were able to comply with this industry standard.

JEDEC level 2 is achieved if no blistering is observed after reflow soldering conditions after conditioning the samples for 168 hrs at 85° C. and 85% relative humidity.

JEDEC level 2a is achieved if no blistering is observed after reflow soldering conditions after conditioning the samples for 696 hrs at 30° C. and 60% relative humidity.

Of the comparative examples, CE-E which included a polyamide 9T based composition recorded the best blister performance, although still considerably lower than the compositions within the scope of the present invention. This finding is to be expected, based upon the lower moisture absorption of the CE-E. Indeed, the blister results within the comparative examples reveal a correlation between blister performance and moisture uptake levels.

The teaching that improved blistering performance is to be achieved through producing a more hydrophobic polyamide which absorbs less moisture is also present in U.S. Pat. No. 6,140,459 and WO2006/135841 which discloses improved blister performance in a polyamide composition comprising repeating units derived from dicarboxylic acid monomers comprising terephthalic acid and aliphatic diamines having 10 to 20 carbon atoms (eg. PA10T). Thus, it is surprising that the examples under the scope of the present invention have superior blister performance, compared to conventional polyamides, despite their relatively high water uptake.

For comparison purposes it is noted that in the cited art U.S. Pat. No. 6,140,459 the blistering was tested after 96 hrs conditioning at 40° C., 95% RH, and applying peak temperatures up to 250° C. In those tests PA 6T/66 already failed at 240° C. and PA 6T/D6 did not even pass 210° C.

In contrast to comparative examples, the compositions of the present invention exhibit isotropic behaviour, as illustrated by the lower variation in the coefficient of linear thermal expansion (CLTE) between normal and parallel directions of the polymer flow. This low variance results in components which are less prone to warp. This property is becoming increasingly important due to the trend towards a reduction in component wall thicknesses. Similar improvements were also observed in respect to mold shrinkage performance.

Bobbins of the present invention also exhibit improved retention of dielectric strength, as illustrated with the comparative testing against PA46 in Table 2.

Likewise stiffness at high temperature, as measured by the temperature of deflection under load (T_{def}), is an increasing important parameter to enable thin wall components to mechanically withstand the high temperature environment encountered during the soldering process. The compositions of the present invention exhibit improved stiffness at high temperature, with component parts able to withstand loads to within 11° C. of their melting point compared to about a 20° C. difference between Tₘ and T_{def} of the PA 66/6T and PA 9T based compositions.

TABLE 2
Performance characteristics of bobbin polyamide compositions

| | E-1 | E-2 | E-3 | E-4 | E-5 | CE-A | CE-B | CE-C | CE-D | CE-E | CE-F |
|---|---|---|---|---|---|---|---|---|---|---|---|
| CLTE Parallel/Normal (×10⁻⁵ K⁻¹) | 3.0/3.7 | 3.0/3.1 | | | | 2.2/5.8 | 2.5/5.0 | 2.5/5.4 | 2.1/6.0 | 3.0/4.0 | |
| CLTE Normal-Parallel (×10⁻⁵ K⁻¹) | 0.7 | 0.1 | | | | 3.6 | 2.5 | 2.9 | 3.9 | 1.0 | |
| % Blister @ 12 hr 85° C./85% | 0 | 0 | | | | | | | 100 | 100 | |
| % Blister @ 48 hr 50° C./95% | 0 | 0 | | | | 100 | | | 100 | 20 | |
| % Blister @ 96 hr 85° C./60% | 0 | 0 | 0 | 20 | 30 | | 100 | 100 | 80 | 40 | 100 |
| % Blister @ 168 hr 85° C./60% | 0 | 20 | | | | | 100 | 100 | 100 | 100 | |
| % Blister @ 696 hr 30° C./60% | 0 | 0 | | | | | 100 | 100 | 80 | 80 | |
| H₂O uptake 50° C. 95% (% wt.) | 2.9 | 2.5 | | | | 2.3 | 3.6 | 4.8 | 2.8 | 1.1 | |
| H₂O uptake (in H₂O) 23° C. (% wt.) | 3.8 | 3.3 | 4.0 | 4.8 | 5.3 | 3.2 | 4.5 | 5.5 | 3.3 | 1.0 | 5.5 |
| Melting temperature Tₘ (° C.) | 318 | 320 | 320 | 311 | 313 | 313 | 295 | 295 | 305 | 305 | 312 |
| Glass transition temp. T_{g} (° C.) | 134 | 135 | 126 | 120 | 110 | 100 | 75 | 75 | 90 | 125 | 142 |
| Temp. of deformation T_{def}. (° C.) | 307 | 309 | 307 | 295 | 297 | 291 | 290 | 290 | 285 | 285 | 282 |
| Tₘ − T_{def} (° C.) | 11 | 11 | 13 | 16 | 16 | 22 | 5 | 5 | 20 | 20 | 30 |
| Dielectric strength -DAM (kV/mm) | 33 | 33 | | | | 36 | 30 | 30 | 37 | 30 | |
| 70° C./62% RH (kV/mm) | 33 | 33 | | | | | 20 | 20 | | | |
| 23° C./100% RH (kV/mm) | 25 | 24 | | | | | 4 | 4 | | | |
| Dielectric constant 23° C. (3 GHz) | 3.4 | | | | | 3.7 | | 4.2 | 3.8 | 3.3 | |
| CTI (V) | 520 | 480 | | | | 520 | 320 | 220 | 520 | 400 | |
| RV pellets/UL bars | 1.95/1.87 | 1.95/1.91 | 2.0/— | | | 2.33/2.41 | | | 1.97/1.95 | | 3.2/— |
| E-mod (GPa) | 13.5 | 16.5 | | | | 13.0 | 12 | 15 | 12 | 13 | |
| Charpy Notched (KJ/m²) | 14 | 17 | | | | 13 | 12 | 11 | 10 | 14 | |
| Spiral flow: 80 MPa (mm) | 153 | 135 | | | | 127 | 110 | 130 | 153 | 177 | |

1. Polyamide composition comprising a semi-aromatic polyamide comprising units derived from aliphatic diamines and dicarboxylic acids and at least a CTI improving additive, wherein:
the dicarboxylic acids (A) consist of a mixture of 5-65 mole % aliphatic dicarboxylic acid and optionally aromatic dicarboxylic acid other than terephthalic acid (A1) and 35-95 mole % terephthalic acid (A2);
the aliphatic diamines (B) consist a mixture of 10-70 mole % of a short chain aliphatic diamine with 2-5 C atoms (B1) and 30-90 mole % of a long chain aliphatic diamine with at least 6 C atoms (B2);
the combined molar amount of terephthalic acid (A2) and the long chain aliphatic diamine (B2) is at least 60 mole %, relative to the total molar amount of the dicarboxylic acids and diamines.

2. Polyamide composition according to claim 1, wherein the polyamide composition has a CTI value of at least 500 V.

3. Polyamide composition according to claim 1, wherein the dicarboxylic acids (A) consist of a mixture of 5-65 mole % aliphatic dicarboxylic acid and 35-95 mole % terephthalic acid.

4. Bobbin for an electrical coil made of an electrically insulating plastic material, characterized in that the electrically insulating plastic material is a polyamide composition comprising a semi-aromatic polyamide comprising units derived from aliphatic diamines and dicarboxylic acids, wherein
a. the dicarboxylic acids (A) consist of a mixture of 5-65 mole % aliphatic dicarboxylic acid and optionally aromatic dicarboxylic acid other than terephthalic acid (A1) and 35-95 mole % terephthalic acid (A2);
b. the aliphatic diamines (B) consist a mixture of 10-70 mole % of a short chain aliphatic diamine with 2-5 C atoms (B1) and 30-90 mole % of a long chain aliphatic diamine with at least 6 C atoms (B2);
c. the combined molar amount of terephthalic acid (A2) and the long chain aliphatic diamine (B2) is at least 60 mole %, relative to the total molar amount of the dicarboxylic acids and diamines.

5. Bobbin according to claim 4, wherein the polyamide composition is a polyamide composition.

6. Bobbin according to claim 4, wherein the bobbin comprises one of the following elements,
at least one seat for receiving a metal pin;
at least one metallic pin integrally moulded with the plastic core;
two flanges each positioned at an end of the plastic core; and/or
a through opening for receiving an element of a metallic and/or magnetic material;
or any combination thereof.

7. Electrical coil comprising a bobbin comprising a plastic core and an electrically conductive winding around the plastic core, wherein the bobbin is a bobbin according to claim 4.

8. Electrical coil according to claim 7, wherein the bobbin comprises a plastic core with one or more integrally moulded metallic pins, a wire wound around the core forming a conductive coil, the wire having at least one wire end attached to one integrally moulded metallic pin and a soldering material providing electrical contact between the one integrally moulded metallic pin and the one end of the wire.

9. Electrical coil according to claim 7, wherein the conductive coil is embedded in and isolated by an external layer consisting of a polyamide composition.

10. Process for making an electrical coil according to claim 7, comprising winding an electrically conductive wire comprising a coating layer around the core of the bobbin, attaching an end of the wire to a metallic pin, burning off the coating layer from the end of the wire and soldering the end of the wire to the metallic pin

11. Electrical and/or electronic assembly comprising a first part and an electrical coil according to claim 7, mounted on the first part.

12. Assembly according to claim 10, wherein the assembly is a transformer, an inductor, a filter, a relay, an electromotor, or a printed circuit board.
